(19) United States
(12) Patent Application Publication
(10) Pub. No.: US 2009/0237891 A1
(43) Pub. Date: Sep. 24, 2009

(54) HEAT SINK EQUIPPED DRIVING CIRCUIT MODULE ASSEMBLY FOR LED LAMP

(75) Inventors: JUN LIU, Shenzhen City (CN); YONG-DONG CHEN, Shenzhen City (CN); SHIH-HSUN WUNG, Tu-Cheng (TW)

Correspondence Address: PCE INDUSTRY, INC.;ATT. Steven Reiss, 458 E. LAMBERT ROAD, FULLERTON, CA, 92835, US

(73) Assignees: Fu Zhun Precision Industry (Shen Zhen) Co., Ltd., Shenzhen City (CN); Foxconn Technology Co., Ltd., Tu-Cheng (TW)

(21) Appl. No.: 12/133,399

(22) Filed: Jun. 5, 2008

(30) Foreign Application Priority Data
Mar. 21, 2008 (CN) 200810066155.X

(51) Int. Cl. H05K 7/20

(52) U.S. Cl. 361/714

(57) ABSTRACT

A driving circuit module assembly includes a driving circuit module and a heat sink assembly to receive and cool the driving circuit module. The heat sink assembly includes a hollow heat sink, a cover abutting against a top portion of heat sink, and a base abutting against a bottom portion of the heat sink. The driving circuit module is mounted on the base and thermally connects therewith, whereby heat generated by the driving circuit module is transferred to the heat sink via the base. A plurality of screws extends through the cover, grooves in an outer surface of the heat sink and the base to threadedly engage with nuts thereby assembling the driving circuit module assembly together.

### BACKGROUND OF THE INVENTION

1. Field of the Invention

The present invention relates to a driving circuit module assembly, and more particularly to a driving circuit module assembly for an LED lamp, which has a heat sink assembly to dissipate heat generated by a driving circuit module of the driving circuit module assembly.

2. Description of Related Art

The technology of LED has been rapidly developed in recent years from indicators to illumination applications. With the features of long-term reliability, environment friendliness and low power consumption, the LED is viewed as a promising alternative for future lighting products, such as LED lamp assembly.

A conventional LED lamp assembly comprises a LED lamp and a driving circuit module assembly electronically connecting with and supplying power to the LED lamp. When the LED lamp assembly operates, a large amount of heat is generated by LEDs of the LED lamp and the driving circuit module. The heat generated by the driving circuit module can adversely affect the operational stability thereof.

What is needed, therefore, is a driving circuit module which has a heat sink assembly to dissipate heat generated therefrom.

### SUMMARY OF THE INVENTION

A driving circuit module assembly includes a driving circuit module and a heat sink assembly to receive and cool the driving circuit module. The heat sink assembly includes a hollow heat sink, a cover abutting against a top portion of heat sink, and a base abutting against a bottom portion of the heat sink. The hollow heat sink has a plurality of fins extending radially and outwardly from an outer surface of the heat sink, and a plurality of grooves in the outer surface of the heat sink. The driving circuit module is mounted on the base of the heat sink assembly and thermally connects therewith, whereby heat generated by the driving circuit module is transferred to the heat sink via the base and further to a surrounding air via the fins of the heat sink. A plurality of screws extends through the cover, the grooves of the heat sink and the base to threadedly engage with nuts, thereby assembling the driving circuit module assembly together.

Other advantages and novel features will become more apparent from the following detailed description of preferred embodiments when taken in conjunction with the accompanying drawings, in which:

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is an exploded view of a driving circuit module assembly in accordance with a preferred embodiment of the present invention;

FIG. 2 is an inverted view of FIG. 1;

FIG. 3 is an assembled view of the driving circuit module assembly of FIG. 1; and

FIG. 4 is an inverted view of FIG. 3.

### DETAILED DESCRIPTION OF THE INVENTION

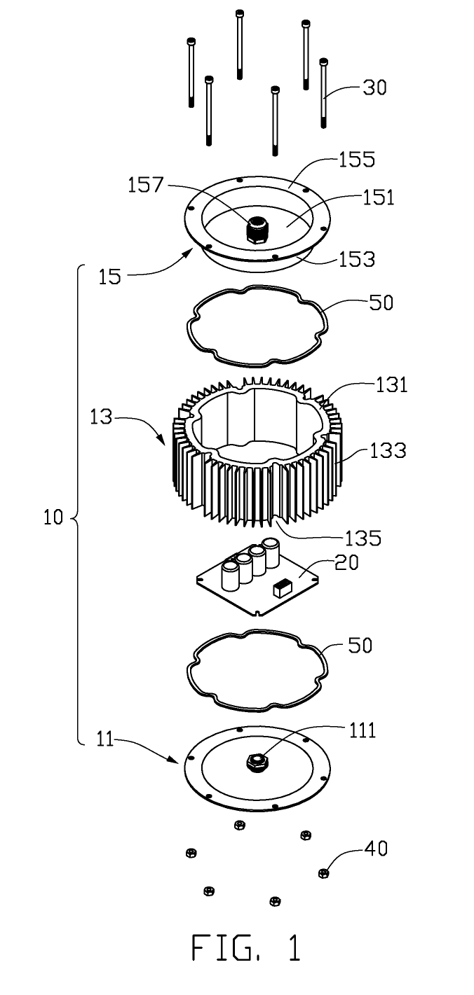

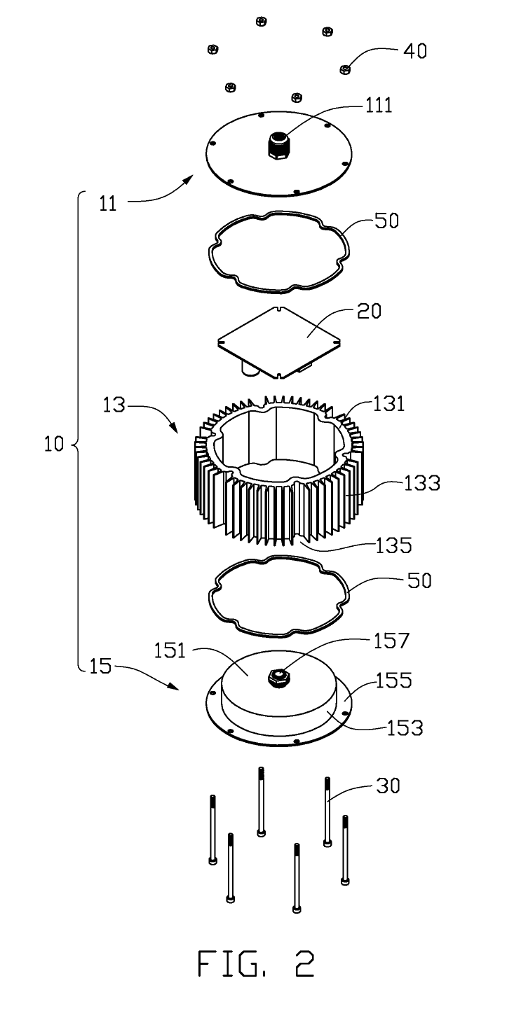

Referring to FIGS. 1-2, a driving circuit module assembly includes a heat sink assembly 10 and a driving circuit module 20 received in the heat sink assembly 10.

The heat sink assembly 10 includes a hollow, cylindrical heat sink 13, a cover 15 covering a top of the heat sink 13, and a base 11 attached to a bottom of the heat sink 13.

The heat sink 13 is integrally formed by aluminum extrusion. The heat sink 13 comprises an annular sidewall 131 and a plurality of fins 133 radially and outwardly extending from an outer surface of the sidewall 131. The fins 133 extend from a top to a bottom of the sidewall 131 and are spaced from each other. The sidewall 131 inwardly protrudes at an equal interval of distance to define corresponding grooves 135 at the outer surface thereof. In this embodiment, the number of the grooves 135 is six.

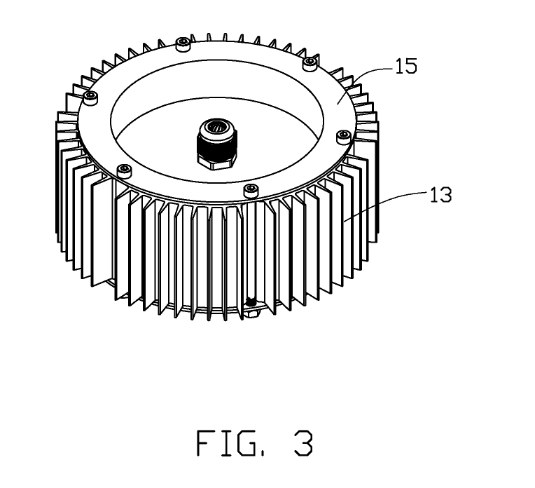

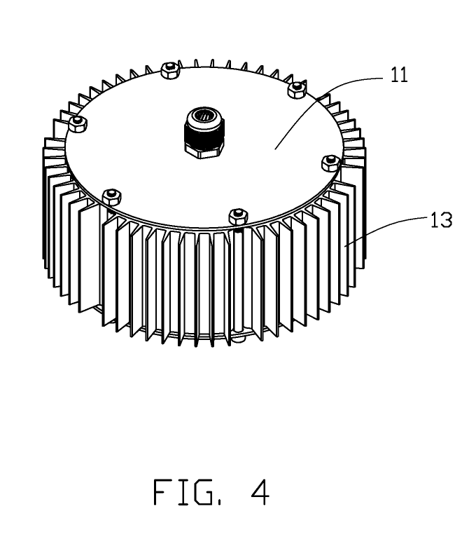

Referring to FIGS. 3-4 also, the cover 15 is made of aluminum. The cover 15 comprises a circular bottom plate 151 received in the heat sink 13, an annular connecting wall 153 extending upwardly and perpendicularly from an outer edge of the bottom plate 151, and a flange 155 extending perpendicularly and outwardly from an upper edge of the connecting wall 153. The flange 155 abuts against a top portion of the sidewall 131 of the heat sink 13. A waterproof connector 157 is mounted on a centre of the bottom plate 151 for connecting with a mating connector (not shown) in electrical connection with LEDs of an LED lamp (not shown).

The base 11 is also made of aluminum and has a diameter larger than a bore diameter of the heat sink 13. The base 11 abuts against a bottom portion of the heat sink 13. A waterproof connector 111 is mounted on a centre of the base 11 for connecting with a mating connector (not shown) in electrical connection with a power source (not shown).

In assembling, the driving circuit module 20 is mounted on a top surface of the base 11 and thermally connects therewith. Six elongated screws 30 extend through the flange 155 of the cover 15, the grooves 135 of the heat sink 13 and the base 11 to engage with six nuts 40 to assemble the driving circuit module assembly 10 together. A pair of gaskets 50 are sandwiched between the cover 15 and the heat sink 13, and the base 11 and the heat sink 13, whereby the cover 15, the base 11 and the heat sink 13 are hermetically connected together.

In use, heat generated by the driving circuit module 20 is absorbed by the heat sink 13 via the base 11 and finally dispersed into ambient cool air via the fins 133. Therefore, a temperature of the driving circuit module 20 can be kept below a set value so that the driving circuit module 20 can always work normally to drive the LEDs to lighten.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A driving circuit module assembly for an LED lamp, the driving circuit module assembly comprising:
a driving circuit module; and
a heat sink assembly to receive and cool the driving circuit module, the heat sink assembly comprising a hollow heat sink, a cover abutting against a top portion of heat sink, and a base abutting against a bottom portion of the heat sink.

2. The driving circuit module assembly as claimed in claim 1, wherein the heat sink is integrally formed by aluminum extrusion and comprises an annular sidewall and a plurality of fins radially and outwardly extending from an outer surface of the sidewall.

3. The driving circuit module assembly as claimed in claim 2, wherein the sidewall inwardly protrudes at an equal interval of distance to define corresponding grooves at the outer surface thereof, screws extending through the cover, the grooves and the base to assemble the cover, the heat sink and the base together.

4. The driving circuit module assembly as claimed in claim 2, wherein the fins extend from top-to bottom of the sidewall and are spaced from each other.

5. The driving circuit module assembly as claimed in claim 2, wherein the cover comprises a bottom plate received in the heat sink, a connecting wall extending upwardly from an outer edge of the bottom plate, and a flange extending outwardly from an upper edge of the connecting wall and abutting against a top portion of the sidewall of the heat sink.

6. The driving circuit module assembly as claimed in claim 5, wherein a waterproof connector is mounted on the bottom plate of the cover adapted for connecting with a mating connector in electrical connection with LEDs of an LED lamp.

7. The driving circuit module assembly as claimed in claim 2, wherein the base has a diameter larger than a bore diameter of the heat sink.

8. The driving circuit module assembly as claimed in claim 7, wherein a waterproof connector is mounted on the base adapted for connecting with a mating connector in electrical connection with a power source.

9. The driving circuit module assembly as claimed in claim 1, wherein a pair of gaskets are sandwiched between the cover and the heat sink, and the base and the heat sink, whereby the cover, the base and the heat sink are hermetically connected together.

10. A driving circuit module assembly comprising:
a driving circuit module; and
a heat sink assembly to receive and cool the driving circuit module, the heat sink assembly comprising a hollow heat sink having a sidewall surrounded the driving circuit module and a plurality of fins extending outwardly from an outer surface of the sidewall, a cover mounted on a top of the heat sink, and a base mounted on a bottom surface of the heat sink;
wherein the cover, the base, and the heat sink are hermetically connected together.

11. The driving circuit module assembly as claimed in claim 10, wherein a plurality of grooves is equidistantly distributed on the outer surface of the sidewall of the heat sink, a plurality of elongated screws extending through an edge of the cover, the grooves, and an edge of the base to engage with nuts to assemble the driving circuit module assembly together.

12. The driving circuit module assembly as claimed in claim 1, wherein a pair of waterproof connectors are mounted on the cover and the base, respectively, adapted for connecting with mating connectors.
